(19) United States
(12) Patent Application Publication
(10) Pub. No.: US 2013/0186461 A1
(43) Pub. Date: Jul. 25, 2013

(54) SOLAR CELL AND METHOD OF MANUFACTURING THE SAME

(71) Applicant: Dong-Jin KIM, Yongin-si (KR)

(72) Inventor: Dong-Jin KIM, Yongin-si (KR)

(21) Appl. No.: 13/556,400

(22) Filed: Jul. 24, 2012

Related U.S. Application Data
(60) Provisional application No. 61/588,819, filed on Jan. 20, 2012.

(51) Int. Cl. H01L 31/0224; H01L 31/18

(52) U.S. Cl. 136/256; 438/98; 257/E31.032

(57) ABSTRACT

A photoelectric device includes a substrate having a generation region and a non-generation region so that the non-generation region is adjacent to the generation region, at least one photoelectric conversion unit in the generation region, and at least one electrode in the non-generation region. The electrode includes an inclined side extending at an acute angle from the substrate.

### CROSS-REFERENCE TO RELATED APPLICATION

The present application claims priority to U.S. Provisional Application No. 61/588,819, filed Jan. 20, 2012, and entitled: “Solar Cell and Method of Manufacturing the Same,” which is incorporated herein by reference in its entirety.

### BACKGROUND

In recent years, there has been a growing interest in exploiting substitute energy sources, e.g., in expectation of the exhaustion of energy sources such as oil and coal. Among the substitute energy sources, solar cells have attracted considerable attention as advanced cells configured to convert solar light energy into electrical energy using, e.g., semiconductor devices.

### SUMMARY

Embodiments may be realized by providing a photoelectric device having a substrate that includes a generation region and a non-generation region and the non generation region is adjacent to the generation region, at least one photoelectric conversion unit in the generation region, and at least one electrode in the non-generation region. The electrode includes an inclined side extending at an acute angle from the substrate.

The acute angle of the inclined side may be about 30° to about 75° with respect to an upper surface of the substrate. The acute angle may be about 45° to about 60°.

A lowermost end of the inclined side of the electrode may be in contact with the upper surface of the substrate and the inclined side may abut a rear electrode on the upper surface of the substrate. Another side of the electrode may be opposite the inclined side of the electrode and may extend from the upper surface of the substrate.

The photoelectric device may include a rear electrode layer on the substrate. The rear electrode layer may include at least one rear electrode extending from the generation region to the non-generation region. A lateral end of the one rear electrode in the non-generation region may be in contact with the inclined side of the electrode. The photoelectric device may include an isolation region adjacent to the electrode having the inclined side and spaced apart from the at least one rear electrode.

The lateral end of the one rear electrode may be inclined. Substantially an entirety of the one lateral end of the rear electrode may abut the inclined side of the electrode.

In the generation region, a light absorption layer, a buffer layer, and a transmissive electrode layer may be sequentially stacked on the rear electrode layer to form the at least one photoelectric conversion unit. In the non-generation region, the light absorption layer, the buffer layer, and the transmissive electrode layer may abut the inclined side of the electrode. In the non generation region, the light absorption layer, the buffer layer, and the transmissive electrode layer may abut a conductive layer of the electrode that forms the inclined side.

A bus bar of the electrode may cover the conductive layer and may be adjacent to an uppermost surface of the transmissive electrode layer. A stacked structure in the non-generation region may include the rear electrode, the light absorption layer, the buffer layer, and the transmissive electrode layer may have a sloped side extending from the substrate at substantially a same angle as the acute angle of the inclined side of the electrode. The transmissive electrode layer may be in electrical contact with the inclined side and may be electrically connected to the one rear electrode such that the transmissive electrode layer provides a by-pass pathway.

Embodiments may also be realized by providing a method of manufacturing a photoelectric device that includes providing a substrate that has a generation region and a non-generation region and the non-generation region is adjacent to the generation region, forming stacked structures in the generation region and the non-generation region and one stacked structure in the generation region corresponds to a photoelectric conversion unit, patterning one stacked structure in the non-generation region to form a trench that has an inclined sidewall and that exposes the substrate, and forming an electrode in the non-generation region. The forming of the electrode includes depositing a conductive material in the trench such that the electrode includes an inclined side extending at an acute angle from the substrate.

Forming the electrode may include performing a first laser scribing process to form the trench and may include performing a second laser scribing process to remove another sidewall of the trench to form an isolation region.

Forming the stacked structures may include sequentially stacking a plurality of layers including a rear electrode layer, a light absorption layer, a buffer layer, and a transmissive electrode layer on the substrate. Patterning the one stacked structure in the non-generation region may include forming the trench through each of the plurality of layers in the one stacked structure.

Forming the electrode may include removing portions of the plurality of layers adjacent to another sidewall of the trench. The other sidewall of the trench may be opposite the inclined sidewall of the trench. The portions of the plurality of layers may be removed by a second laser scribing process such that the electrode includes the inclined side and another side extends from the substrate. Forming the trench may include patterning a rear electrode in the non-generation region such that a lateral end of the rear electrode has a slope that corresponds to a slope of the inclined side of the electrode. The lateral end of the rear electrode may abut the inclined side of the electrode.

### BRIEF DESCRIPTION OF THE DRAWINGS

Features will become apparent to those of ordinary skill in the art by describing in detail exemplary embodiments with reference to the attached drawings in which:

FIG. 1 illustrates a plan view of a solar cell according to an exemplary embodiment.

FIG. 2 illustrates a cross-sectional view of the solar cell according to an exemplary embodiment, which is taken along a line X-X of FIG. 1.

FIG. 3 illustrates a cross-sectional view of the solar cell according to another exemplary embodiment, which is taken along a line X-X of FIG. 1.

FIGS. 4A to 4H illustrate cross-sectional views depicting stages in an exemplary method of manufacturing the solar cell of FIG. 2.

FIGS. 5A to 5H illustrate cross-sectional views depicting stages in an exemplary method of manufacturing the solar cell of FIG. 3.

### DETAILED DESCRIPTION OF THE INVENTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. Like reference numerals refer to like elements throughout. In the drawings, the dimensions, e.g., thicknesses or widths, of layers and/or regions may be exaggerated for clarity.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section.

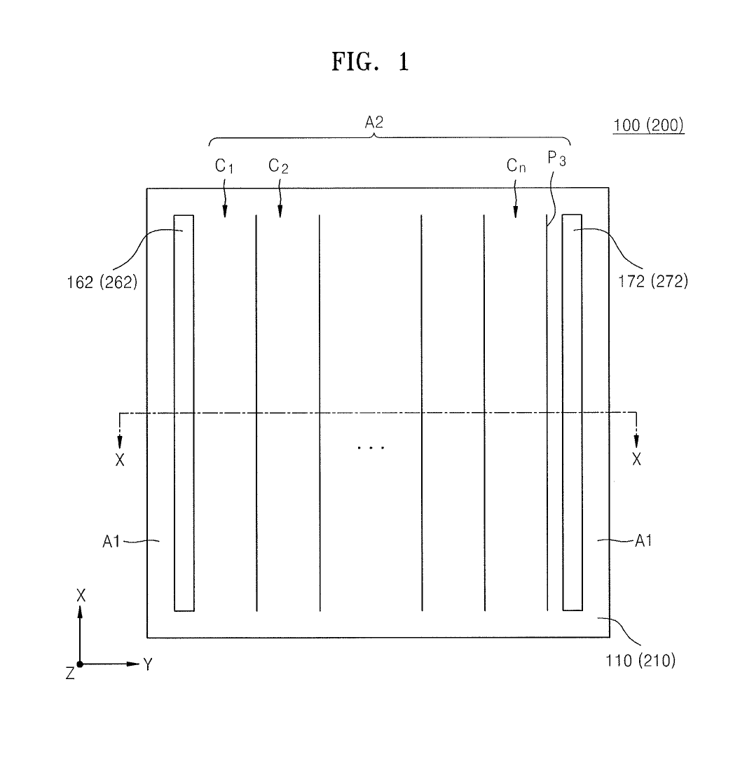

FIG. 1 illustrates a plan view of a solar cell according to an exemplary embodiment, and FIG. 2 illustrates a cross-sectional view of the solar cell, which is taken along a line X-X of FIG. 1.

Referring to FIGS. 1 and 2, the solar cell according to an exemplary embodiment may include an edge region A1 formed along an edge using, e.g., an edge isolation process. The solar cell may include a generation region A2 surrounded by the edge region A1, e.g., lateral sides of generation region A2 may abut the edge region A1.

The generation region A2 may include a plurality of photoelectric conversion units C1 to Cn, e.g., that are disposed in a plurality of columns. First and second electrodes 160 and 170 including first and second bus bars 162 and 172, respectively, may be formed on opposing lateral sides of the generation region A2. For example, the first and second electrodes 160 and 170 may be formed on opposing lateral sides of the generation region A2, respectively, that are each adjacent to the edge region A1.

The edge region A1 may include an isolation region. In the solar cell 100 according to an exemplary embodiment, a patterning process for forming the first and second electrodes 160 and 170 and an edge isolation process for forming the isolation region may be performed in the same equipment, e.g., at a same time. The first and second electrodes 160 and 170 may be disposed right next to the edge region A1, e.g., to abut the isolation region.

The solar cell 100 may use a chalcogenide-based compound therein. The solar cell 100, according to an exemplary embodiment, may include a substrate 110, a rear electrode layer 120 disposed on the substrate 110, a light absorption layer 130, and a buffer layer 140 disposed on the rear electrode layer 120, and a transmissive electrode layer 150 disposed on the buffer layer 140.

Portions of the rear electrode 120 in the generation region A2 may be separated, e.g., spaced apart, by first separation grooves P1. At least one portion of the rear electrode 120 may extend from the generation region to the non-generation region. The portions of the rear electrode 120 extending into the non-generation region may be spaced apart from the edge region A1, e.g., spaced apart from the isolation region, by the first and second electrodes 160 and 170, respectively. Portions of the buffer layer 140 may be separated, e.g., spaced apart, by a second separation groove P2 extending through one of the plurality of photoelectric conversion units C1 to Cn. Accordingly, second separation grooves P2 may extend through the plurality of photoelectric conversion units C1 to Cn. Portions of the transmissive electrode layer 150, and adjacent photoelectric conversion units C1 to Cn, may be separated by third separation grooves P3.

The substrate 110 may be a glass substrate having a high optical transmittance or a polymer substrate. For example, the glass substrate may be fanned of sodalime glass or high-strained-point soda glass. The glass substrate may be formed of low-iron reinforced glass to protect internal elements from external shock and increase transmittance of solar light. In particular, at a process temperature higher than about 500° C., Na+ ions may flow out from low-iron sodalime glass, thereby further improving efficiency of the light absorption layer 130 formed of copper-indium-gallium-selenide (Cu(In, Ga)Se₂) (CIGS). The polymer substrate may be formed of a flexible polymer, such as polyimide. Embodiments are not limited thereto, e.g., other types of substrates that are suitable for use in a photoelectric device may form the substrate 110.

The rear electrode layer 120 may be formed of a metal material having a high conductivity and a high light reflectance, such as molybdenum (Mo), aluminum (Al), or copper (Cu). The rear electrode layer 120 may be configured so that electric charges generated due to a photoelectric effect may be collected and light transmitted through the light absorption layer 130 may be reflected and re-absorbed by the light absorption layer 130. According to an exemplary embodiment, the rear electrode layer 120 may include Mo in consideration of a high conductivity, an ohmic contact of the rear electrode layer 120 with the light absorption layer 130, and high-temperature stability maintained in the atmosphere of selenium (Se). The rear electrode layer 120 may be formed of a single metal layer or formed of a multiple layer to enable adhesion of the rear electrode layer 120 with the substrate 110 and/or ensure a resistance characteristic of the rear electrode layer 120.

The rear electrode layer 120 may be doped with alkali ions, such as sodium (Na). For example, during growth of the light absorption layer 130 as will be described in detail later, the alkali ions doped into the rear electrode 120 may be mixed with the light absorption layer 130. Thus, the mixed alkali ions may have an advantageous structural influence on the light absorption layer 130 and/or improve conductivity of the light absorption layer 130, thereby increasing an open voltage V_{oc} of the solar cell.

The light absorption layer 130 may form a P-type semiconductor layer formed of a CIGS-based compound including copper (Cu), indium (In), gallium (Ga), and selenium (Se) and absorb incident solar light. Alternatively, the light absorption layer 130 may form a P-type semiconductor layer formed of a CuInSe₂ (CIS)-based compound including Cu, In, and Se. The light absorption layer 130 may also be formed within the first separation groove P1, which is configured to divide the rear electrode layer 120. For example, the light absorption layer 130 may fill the first separation grooves P1 so as to be arranged between adjacent regions of the rear electrode layer 120.

The buffer layer 140 may lessen a difference in bandgap between the light absorption layer 130 and the transmissive electrode layer 150. The buffer layer 140 may reduce a re-combination of electrons and holes at an interface between the light absorption layer 130 and the transmissive electrode layer 150. The buffer layer 140 may be formed of cadmium sulfide (CdS), zinc sulfide (ZnS), indium sulfide (In₂S₃), or zinc magnesium oxide (ZnₓMg₍₁₋ₓ₎O).

Each of the light absorption layer 130 and the buffer layer 140 may be divided into a plurality of regions/portions by the second separation grooves P2. The second separation grooves P2 may be formed parallel to the first separation grooves P1 in a different position from the first separation grooves P1, and a top surface of the rear electrode layer 120 may be exposed by the second separation grooves P2.

The transmissive electrode layer 150 may form a PN junction with the light absorption layer 130. The transmissive electrode layer 150 may be formed of a transparent conductive material, such as boron-doped zinc oxide (ZnO:B), indium tin oxide (ITO), and/or indium zinc oxide (IZO). The transmissive electrode layer 150 may capture electric charges generated due to a photoelectric effect. Although not shown, a top surface of the transmissive electrode layer 150 may be textured to reduce reflection of incident solar light and/or increase light absorbed in the light absorption layer 130.

The transmissive electrode layer 150 may also be formed in the second separation grooves P2, e.g., may fill the separation grooves P2. The transmissive electrode layer 150 within the second separation grooves P2 may be in contact with portions of the rear electrode layer 120 exposed by the second separation grooves P2. The transmissive electrode layer 150 may electrically connect the plurality of portions into which the light absorption layer 130 is divided by the second separation grooves P2.

The transmissive electrode layer 150 may be divided into a plurality of portions by the third separation grooves P3, which are formed in a different position from the first and second separation grooves P1 and P2. The third separation grooves P3 may be formed parallel to, e.g., to extend in a direction parallel to extending directions of, the first and second separation grooves P1 and P2. The third separation grooves P3 may extend to the top surface of the rear electrode layer 120 to form a plurality of photoelectric conversion units C1 to Cn.

The third separation grooves P3 may be filled with an insulating material, such as the air, to form insulating layers between the plurality of photoelectric conversion units C1 to Cn so that the plurality of photoelectric conversion units C1 to Cn may be connected in series in a traverse direction of FIG. 1 (which traverse direction may be vertical to the third separation grooves P3).

Non-generation regions NE may be disposed on both sides of the plurality of photoelectric conversion units C1 to Cn. The non-generation regions NE may be adjacent to and/or abut the edge region A1. The first and second electrodes 160 and 170 may be disposed in the non-generation regions NE in order to, e.g., draw power generated by the plurality of photoelectric conversion units C1 to Cn, which are connected in series.

The first electrode 160 may be formed in a left non-generation region NE interposed between a first photoelectric conversion unit C1 and the edge region A1. The second electrode 170 may be formed in a right non-generation region NE interposed between an N-th photoelectric conversion unit Cn and the edge region A1.

The first electrode 160 may include the first bus bar 162 and a first conductive layer 161. The first conductive layer 161 may be configured to electrically connect the first bus bar 162 with the rear electrode layer 120. The second electrode 170 may include the second bus bar 172 and a second conductive layer 171. The second conductive layer 171 may be configured to electrically connect the second bus bar 172 with the rear electrode layer 120. According to an exemplary embodiment, the first and second bus bars 162 and 172 may be formed of a metal material, such as a wire, and the first and second conductive layers 161 and 171 may be formed of a paste used for a soldering process.

The first and second electrodes 160 and 170 may be electrically connected to the rear electrode layer 120 and draw electric charges (i.e., current) generated by the plurality of photoelectric conversion units C1 to Cn due to a photoelectric effect. For example, the first and second conductive layers 161 and 171 of the first and second electrodes 160 and 170, respectively, may be in direct contact with and may be electrically connected to the rear electrode layer 120. Accordingly, electric charges may move along a path formed by a contact of the rear electrode layer 120 with the first and second conductive layers 161 and 171.

The first and second electrodes 160 and 170 may have inclined sides extending at an angle, e.g., an acute angle, from an upper surface of the substrate 110. The inclined sides of the first and second electrodes 160 and 170 may abut the rear electrode layer 120, e.g., may abut the lateral surface of the rear electrode layer 120. For example, the first and second electrodes 160 and 170 may abut an entirety of the lateral surface of the rear electrode layer 120, which lateral surface of the rear electrode layer 120 also extends from the substrate 110 at an acute angle. Other sides of the first and second electrodes 160 and 170 that oppose the inclined sides may not be inclined, e.g., may not have a gradual slope as compared to the inclined sides. The other sides of the first and second electrodes 160 and 170 opposing the inclined sides may be curved or may be substantially perpendicular to the upper surface of the substrate 110. The other sides of the first and second electrodes 160 and 170 that oppose the inclined sides may abut the edge region A1.

According to an exemplary embodiment, the first and second conductive layers 161 and 171 may be formed on inclined surfaces formed on lateral surfaces of the non-generation regions NE so that the first and second conductive layers 161 and 171 have inclined surfaces. The inclined surfaces of the non-generation regions NE may be formed by partially removing lateral surfaces of the rear electrode layer 120, the light absorption layer 130, the buffer layer 140, and the transmissive electrode layer 150. All the lateral surfaces of the rear electrode layer 120, the light absorption layer 130, the buffer layer 140, and the transmissive electrode layer 150 forming the non-generation regions NE may have a same slope, e.g., with respect to the upper surface of the substrate 110. The inclined surfaces of the first and second conductive layers 161 and 171 may also have the same slope with respect to the upper surface of the substrate 110. Alternatively, the lateral surfaces of the non-generation regions NE may have various slopes according to positions. For example, each of the lateral surfaces of the rear electrode layer 120 may be formed to have a different slope from the lateral surfaces of the remaining layers, e.g., so as to formed a stepped surface in the non-generation region NE.

An angle θ may correspond to the slope of the inclined sides of at least one of the first and second electrodes 160 and 170. At the angle θ of the inclined sides, bottom surfaces of the first and second electrodes 160 and 170 may range from about 30° to about 75° with respect to the upper surface of the substrate 110. The bottom surfaces of the first and second electrodes 160 and 170 may be in direct contact with the upper surface of the substrate 110 so as to extend from the upper surface of the substrate 110. The range for the angle θ is not limited thereto, e.g., the range may be within a narrower range such as about 45° to about 60° with respect to the upper surface of the substrate 110.

The angle θ may also correspond to a slope of the lateral surface of the rear electrode layer 120 with respect to the upper surface of the substrate 110. At the angle θ of the lateral surface of the rear electrode layer 120, a bottom surface of the lateral side of the rear electrode layer 120 may range from about 30° to about 75° with respect to the upper surface of the substrate 110. The bottom surface of the lateral side of the rear electrode layer 120 may be in direct contact with the upper surface of the substrate 110 so as to extend from the upper surface of the substrate 110. The range for the angle θ is not limited thereto, e.g., the range may be within a narrower range such as about 45° to about 60° with respect to the upper surface of the substrate 110.

When the angle θ exceeds an upper limit, contact areas between the first and second conductive layers 161 and 171 and the rear electrode layer 120 may be reduced, e.g., thereby precluding an electrical connection between the first and second conductive layers 161 and 171 and the rear electrode layer 120. When the angle θ is less than a lower limit, an area (i.e., a dead area) occupied by the non-generation regions NE may increase, and the cost of materials of the first and second conductive layers 161 and 171 may also increase.

The light absorption layer 130, the buffer layer 140, and the transmissive electrode layer 150 may also have inclined lateral surfaces. For example, each of the rear electrode layer 120, the light absorption layer 130, the buffer layer 140, and the transmissive electrode layer 150 may form one continuous lateral surface that is arranged at the angle θ with respect to the upper surface of the substrate 110.

According to an exemplary embodiment, a bottom surface of the inclined lateral surface of light absorption layer 130 may extend at the angle θ, which is within the range of about 30° to about 75° and/or about 45° to about 60°, with respect to an upper surface of the rear electrode layer 120. A bottom surface of the inclined lateral surface of the buffer layer 140 may extend at the angle θ, which is within the range of about 30° to about 75° and/or about 45° to about 60°, with respect to an upper surface of the light absorption layer 130. A bottom surface of the inclined lateral surface of the transmissive electrode layer 150 may extend at the angle θ, which is within the range of about 30° to about 75° and/or about 45° to about 60°, with respect to an upper surface of the buffer layer 140.

The first and second electrodes 160 and 170 may be electrically connected to the rear electrode layer 120 via a contact region. The non-generation regions NE may have a predetermined width so as to enable a contact of the first and second electrodes 160 and 170 with the rear electrode layer 120. For example, the non-generation regions NE may be formed to substantially the same width as the first and second electrodes 160 and 170, e.g., to correspond to width of the first and second bus bars 162 and 172. Alternatively, the width of the non-generation regions NE may be greater than a width of the first and second electrodes 160 and 170, e.g., to provide a by-pass pathway for electrical connection to the first and second electrodes 160 and 170.

The solar cell 100 according to the above-described embodiment may be structured such that the first and second electrodes 160 and 170 are formed next to the edge regions A1. Accordingly, the non-generation regions NE, where no photoelectric conversion occurs, may be minimized and the area of the generation region A2, where photoelectric conversion occurs, may be maximized. Since the first and second electrodes 160 and 170 may be electrically connected to the rear electrode layer 120, e.g., to provide a path through which charges are transported, a resistance may be greatly reduced as compared with a case where the first and second electrodes 160 and 170 are electrically connected instead to only the transmissive electrode layer 150.

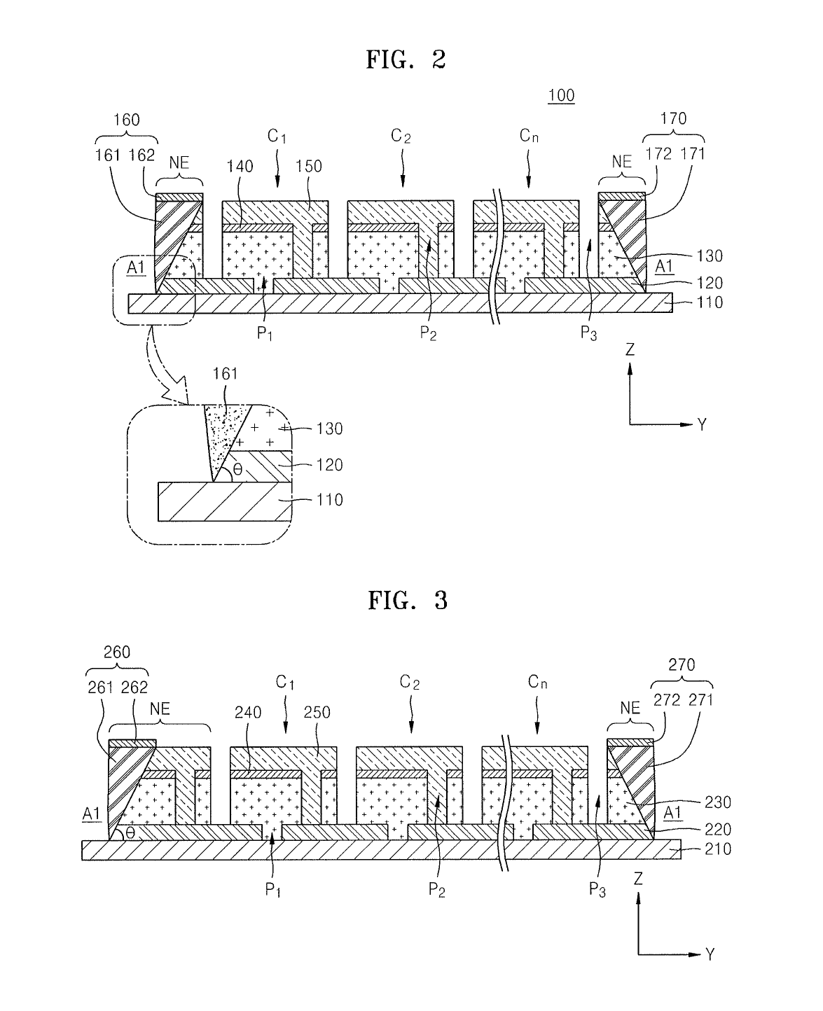

FIG. 3 illustrates a cross-sectional view of the solar cell, according to another exemplary embodiment that is taken along a line X-X of FIG. 1. Differences between this exemplary embodiment and the above exemplary embodiment are mainly described.

Referring to FIG. 3, a solar cell 200 according to an exemplary embodiment may include an edge region A1 formed along an edge using an edge isolation process and a generation region A2 surrounded by the edge region A1. In the solar cell 200, a patterning process for forming first and second electrodes 260 and 270 and a process of forming the edge region A1, which may be an isolation region, may be performed in the same equipment. The first and second electrodes 260 and 270 may be formed right next to, e.g., abutting, the edge region A1.

The solar cell 200 may use a chalcogenide-based compound therein. The respective layers constituting the solar cell 200 may be substantially the same as or similar to the layers of the solar cell 100 described with reference to FIG. 2, as such a detailed description thereof will be omitted for brevity. The solar cell 200 may include a substrate 210, a rear electrode layer 220 disposed on the substrate 210 and separated by the first separation groove P1, a light absorption layer 230, a buffer layer 240 disposed on the rear electrode layer 220 and separated by the second separation groove P2, and a transmissive electrode layer 250 disposed on the buffer layer 240 and separated by the third separation groove P3.

The third separation groove P3 formed among a plurality of photoelectric conversion units C1 to Cn included in the generation region A2 may be filled with an insulating material, such as the air, to form an insulating layer. The plurality of photoelectric conversion units C1 to Cn may be connected in series along the lateral direction of FIG. 1, which may be vertical to the third separation groove P3.

Non-generation regions NE may be disposed on both sides of the plurality of photoelectric conversion units C1 to Cn. First and second electrodes 260 and 270 may be disposed in the non-generation regions NE to, e.g., draw power generated by the plurality of photoelectric conversion units C1 to Cn connected in series.

The solar cell 200 may differ from the solar cell 100 shown in FIG. 1 in that a second separation groove P2 may be formed in the non-generation region NE interposed between the first photoelectric conversion unit C1 and the edge region A1. The second separation groove P2 may also be formed in the non-generation region NE interposed between the N-th photoelectric conversion unit Cn and the edge region A1 (not shown) or the second separation groove P2 may be formed only in the non-generation region NE interposed between the N-th photoelectric conversion unit Cn and the edge region A1 (not shown).

Since the components of the solar cell 200 may be understood with the same components of the solar cell 100 described above, hereinafter, differences between the solar cells 200 and 100 will be mainly described. Further, the exemplary embodiment where the second separation groove P2 is formed in the left non-generation region NE is described; however, embodiments are not limited thereto. For example, the second separation groove P2 may be formed in the right non-generation region NE or in both the left and right non-generation regions NE.

The transmissive electrode layer 250 may be formed within the second separation groove P2 formed in the left non-generation region NE and may be formed to be in contact with a portion of the rear electrode layer 220 in the left non-generation region NE. According to the exemplary embodiment, the rear electrode layer 220 has a higher conductivity than the transmissive electrode layer 250 so that charges generated due to photoelectric conversion may move along the rear electrode layer 220 having the relatively high conductivity. That is, the charges generated due to photoelectric conversion may move through the rear electrode layer 220 toward a first conductive layer 261 of the first electrode 260 and then a first bus bar 262. The charges may also move through the rear electrode layer 220 toward the second conductive layer 271 of the second electrode 270 and then a second bus bar 272.

However, in preparation for occurrence of a contact failure between the first conductive layer 261 and the rear electrode layer 220, the transmissive electrode layer 250 formed in the second separation groove P2 contacts with the rear electrode layer 220 and forms a subsidiary path, e.g., a by-pass pathway, through which charges may be transported to the first electrode 260. For example, when the first conductive layer 261 becomes out of contact with the rear electrode layer 220, e.g., due to a failure in a manufacturing process and/or external shock applied during an operation of the solar cell 200, the charges generated due to photoelectric conversion may move through the transmissive electrode layer 250 contacted with the rear electrode layer 220 via the second separation groove P2. That is, the charges generated due to photoelectric conversion may move through the transmissive electrode layer 250 toward the first conductive layer 261 and the first bus bar 262.

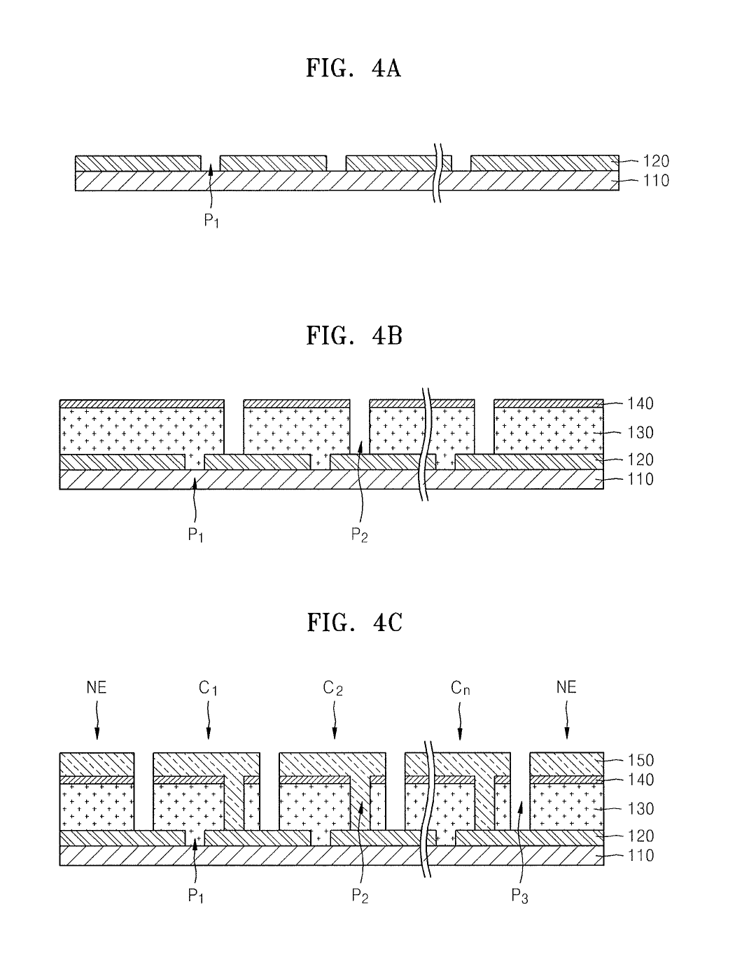

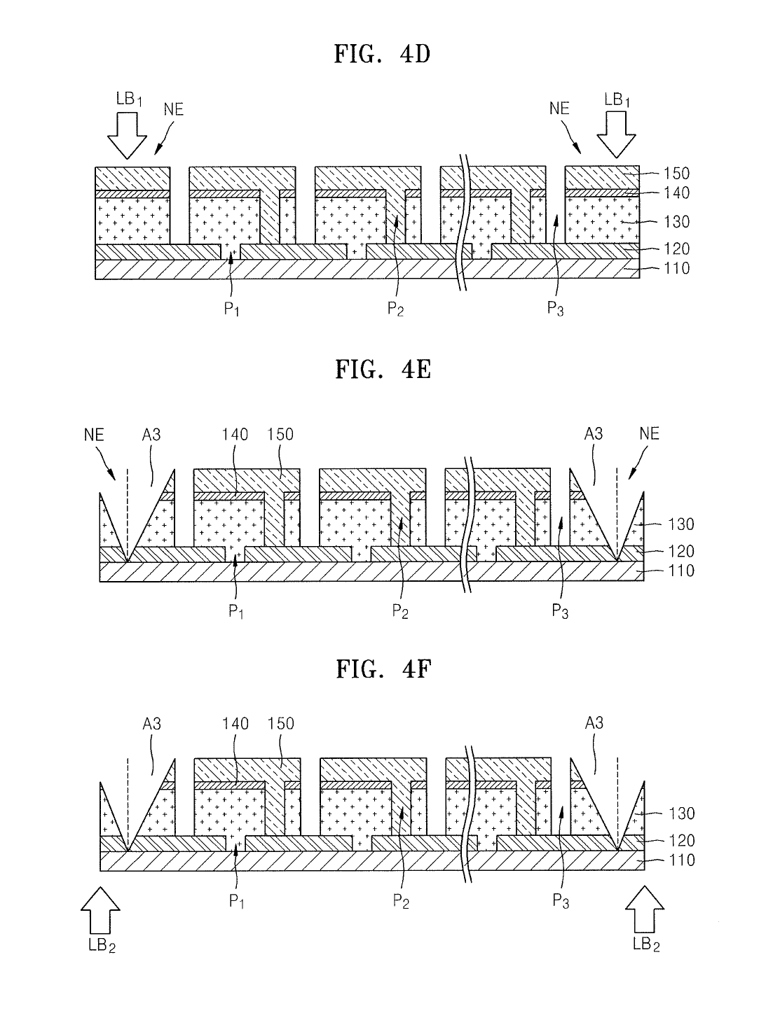

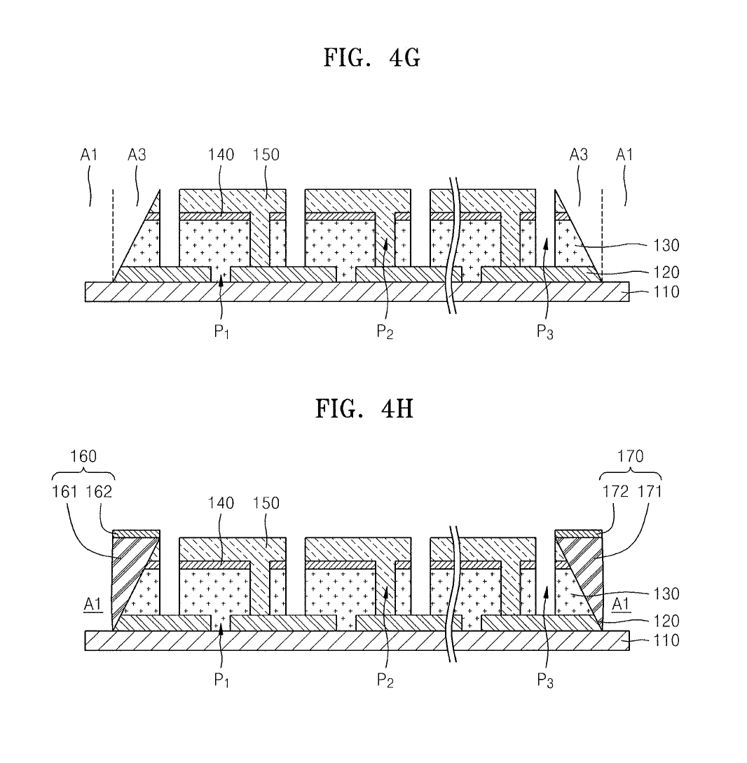

FIGS. 4A to 4H illustrate cross-sectional views depicting stages in an exemplary method of manufacturing the solar cell of FIG.

Referring to FIG. 4A, first, a rear electrode layer 120 may be formed on a substrate 110 and divided into a plurality of portions using a first patterning process. For example, the rear electrode layer 120 may be formed by coating a conductive paste on the substrate 110 and performing a thermal process or may be formed by a plating method. Alternatively, the rear electrode layer 120 may be formed by sputtering using, e.g., a Mo target.

The first patterning process may include, e.g., a laser scribing process. The laser scribing process may include evaporating a partial region of the rear electrode layer 120 by irradiating laser beams toward the substrate 110 from below the substrate 110. Thus, the rear electrode layer 120 may be divided by a plurality of first separation grooves P1 into a plurality of portions spaced a predetermined distance apart from one another.

Referring to FIG. 4B, a light absorption layer 130 and a buffer layer 140 may be formed. Second separation grooves P2 extending through the light absorption layer 130 and the buffer layer 140 may be formed using a second patterning process.

The light absorption layer 130 may be formed using a co-evaporation method or a sputtering/selenization method. In the co-evaporation method, the formation of the light absorption layer 130 may include injecting Cu, In, Ga, and Se into a small electrical furnace installed in a vacuum chamber and heating the electrical furnace for vacuum evaporate coating. In the sputtering/selenization method, the formation of the light absorption layer 130 may include forming a CIG-based metal precursor layer on the rear electrode layer 120 using a Cu target, an In target, and a Ga target and performing heat-treatment in a hydrogen selenide (H₂Se) gas atmosphere so that the CIG-based metal precursor layer may react with Se to form a CIGS-based light absorption layer 130. Alternatively, the light absorption layer 130 may be formed using an electro-deposition method or a molecular organic chemical vapor deposition (MOCVD) method.

While the present embodiment describes a case where the CIGS-based light absorption layer 130 is formed, embodiments are not limited thereto. For example, a CIS-based light absorption layer 130 may be formed.

The buffer layer 140 may lessen a difference in bandgap between the light absorption layer 130, which may be P-type, and the transmissive electrode layer 150, which may be N-type. The buffer layer 140 may reduce a re-combination of electrons and holes at an interface between the light absorption layer 130 and the transmissive electrode layer 150. The buffer layer 140 may be formed using a chemical bath deposition (CBD) process, an atomic layer deposition (ALD) process, or an ion layer gas reaction (ILGAR) process.

As described above, after forming the light absorption layer 130 and the buffer layer 140, a second patterning process may be performed. The second patterning process may be performed by, e.g., a mechanical scribing process using a pointed member, such as a needle, moving along a line that is parallel to the first separation groove P1 and spaced apart from the first separation grooves P1. However, embodiments are not limited thereto, e.g., the second patterning process may be performed using a laser.

Due to the second patterning process, the light absorption layer 130 and the buffer layer 140 may be divided into a plurality of portions, and the second separation grooves P2 may extend to a top surface of the rear electrode layer 120 so as to expose the rear electrode layer 120.

Referring to FIG. 4C, the transmissive electrode layer 150 may be formed on the buffer layer 140 and to fill the second separation grooves P2. After forming the transmissive electrode layer 150, a third patterning process may be performed to form the third separation grooves P3.

The transmissive electrode layer 150 may be formed of a transparent conductive material, such as ZnO:B, ITO, or IZO. The transmissive electrode layer 150 may be formed by an MOCVD process, an LPCVD process, or a sputtering process.

The transmissive electrode layer 150 may be formed in the second separation grooves P2 and may electrically connect the plurality of portions into which the light absorption layer 130 is divided by the second separation grooves P2.

The third patterning process may be performed using a mechanical scribing process. Third separation grooves P3 formed using the third patterning process may extend to the top surface of the rear electrode layer 120 to form a plurality of photoelectric conversion units C1 to Cn. Also, the third separation grooves P3 may be filled with, e.g., the air, to form an insulating layer.

By forming the third separation grooves P3, the plurality of photoelectric conversion units C1 to Cn may be formed, and non-generation regions NE may be formed on both sides of the plurality of photoelectric conversion units C1 to Cn. The rear electrode layer 120, the light absorption layer 130, the buffer layer 140, and the transmissive electrode layer 150 may be sequentially formed in each of the non-generation regions NE, but no separation groove may be formed in each of the non-generation regions NE.

The transmissive electrode layer 150 may have a textured top surface formed by a texturing process (not shown). The texturing process refers to formation of a rough pattern on a surface using a physical or chemical process. When the transmissive electrode layer 150 has a rough surface using a texturing process, the reflectance of incident light may be reduced to increase a captured amount of light. Thus, an optical-loss reduction effect may be obtained.

Referring to FIGS. 4D and 4E, portions in the non-generation regions NE may be selectively removed to form electrode regions A3, e.g., stacked structures in the non-generation regions NE including the rear electrode layer 120, the light absorption layer 130, the buffer layer 140, and the transmissive electrode layer 150 may have portions thereof removed. For example, a approximately V-shaped groove that includes the electrode regions A3 may be formed in the stacked structures such that portions of the stacked structure surrounding the V-shaped groove may remain on the substrate 110. The V-shaped groove may be formed so that a width of the groove decreases toward an end point, and the end point corresponds to a region adjacent to the upper surface of the substrate 110. The portions of the stacked structures in the non-generation regions NE may be removed to form the inclined surfaces of the rear electrode layer 120 so as to increase contact areas between the rear electrode layer 120 and first and second electrodes 160 and 170 to be formed during a subsequent process.

The removal of the portions in the non-generation regions NE may be performed by a laser scribing process using a laser having, e.g., a wavelength of about 1060 nm to about 1064 nm, a pulse width of about 10 ns to about 100 ns, and a power of about 0.5 W to about 15 W.

During the removal of the portions in the non-generation regions NE, laser beams LB1 may travel along a direction toward the rear electrode layer 120 from above the transmissive electrode layer 150. The transmissive electrode layer 150, the buffer layer 140, the light absorption layer 130, and the rear electrode layer 120 may be sequentially removed due to energy of the laser beams LB1. In this case, the V-shaped groove may be formed using the laser beams LB1 that have approximately a V-shape so that lateral surfaces of the rear electrode layer 120, the light absorption layer 130, the buffer layer 140, and the transmissive electrode layer 150 may have the same slope. However, embodiments for forming the V-shaped groove are not limited thereto.

Due to the laser scribing process, the lateral surface of the rear electrode layer 120 may include the inclined lateral surface. For example, a slope of the lateral surface of the rear electrode layer 120, that is, an angle of the lateral surface of the rear electrode layer 120 relative to a bottom-most surface of the rear electrode layer 120 (from which the lateral surface of the rear electrode layer 120 extends) may range from about 30° to about 75°, e.g., from about 45° to about 60°.

Referring to FIGS. 4F and 4G, an edge isolation process may be performed. For instance, the rear electrode layer 120, the light absorption layer 130, the buffer layer 140, and the transmissive electrode layer 150 disposed in regions adjacent to the electrode region A3, e.g., disposed right next to the electrode regions A3, may be removed. Accordingly, the edge region A1, e.g., an isolation region, may be formed adjacent to the electrode regions A3.

The edge region A1 may be formed by the removal of the rear electrode layer 120, the light absorption layer 130, the buffer layer 140, and the transmissive electrode layer 150 disposed at outermost sides of the non-generation regions NE by a laser scribing process. The laser scribing process may be performed using a laser having, e.g., a wavelength of about 1060 nm to about 1064 nm, a pulse width of about 10 ns to about 100 ns, and a power of about 200 W to about 1000 W. However, embodiments for forming the edge region A1 are not limited thereto.

According to an exemplary embodiment, during the forming of the edge region A1, laser beams LB2 may travel toward the substrate 110 from below the substrate 110. The rear electrode layer 120, the light absorption layer 130, the buffer layer 140, and the transmissive electrode layer 150 may evaporate due to energy of the laser beams LB2, thereby forming the edge region A1. The edge region A1 may be formed around an edge of the substrate 110.

The process of forming the electrode regions A3 and the edge isolation process described with reference to FIGS. 4D, 4E, 4F, and 4G may be performed in the same equipment by varying an output and direction of laser beams.

Since the laser beams LB1 used for forming the electrode regions A3 are incident in a different direction and have a different optical axis from the laser beams LB2 used for the edge isolation process, the laser beams LB1 and the laser beams LB2 may be disposed in the same equipment without causing interference between the optical axes thereof. Accordingly, the formation of the electrode regions A3 and edge regions A1 by the edge isolation process may be simultaneously performed using two different kinds of lasers included in the same equipment. For example, the two different kinds of lasers may be applied at a same time within the same equipment.

Referring to FIG. 4H, first and second electrodes 160 and 170 may be formed. The first electrode 160 may include a first bus bar 162 and a first conductive layer 161, which is configured to electrically connect the first bus bar 162 and the rear electrode layer 120. The second electrode 170 may include a second bus bar 172 and a second conductive layer 171, which is configured to electrically connect the second bus bar 172 and the rear electrode layer 120. The first and second conductive layers 161 and 171 may include a paste used for a soldering process, and the first and second bus bars 162 and 172 may include a metal material, such as a wire.

A soldering paste may be coated to cover the inclined lateral surfaces of the rear electrode layer 120 exposed during the formation of the electrode regions A3. A wire may be disposed on the soldering paste and sintered, such that the first and second electrodes 160 and 170 are formed. The soldering paste may be coated on the entire inclined lateral surface of the rear electrode layer 120 so that the first and second conductive layers 161 and 171 form the inclined lateral surfaces of the first and second electrodes 160 and 170, respectively. The wire of the first and second bus bars 162 and 172 may extend above the first and second conductive layers 161 and 171, e.g., the first and second bus bars 162 and 172 may not have inclined lateral surfaces.

In another exemplary method, the rear electrode layer 120 exposed during the formation of the electrode regions A3 may be combined with the wire using a soldering process so that the inclined lateral surfaces of the rear electrode layer 120 may be electrically connected to the wire using a soldered paste.

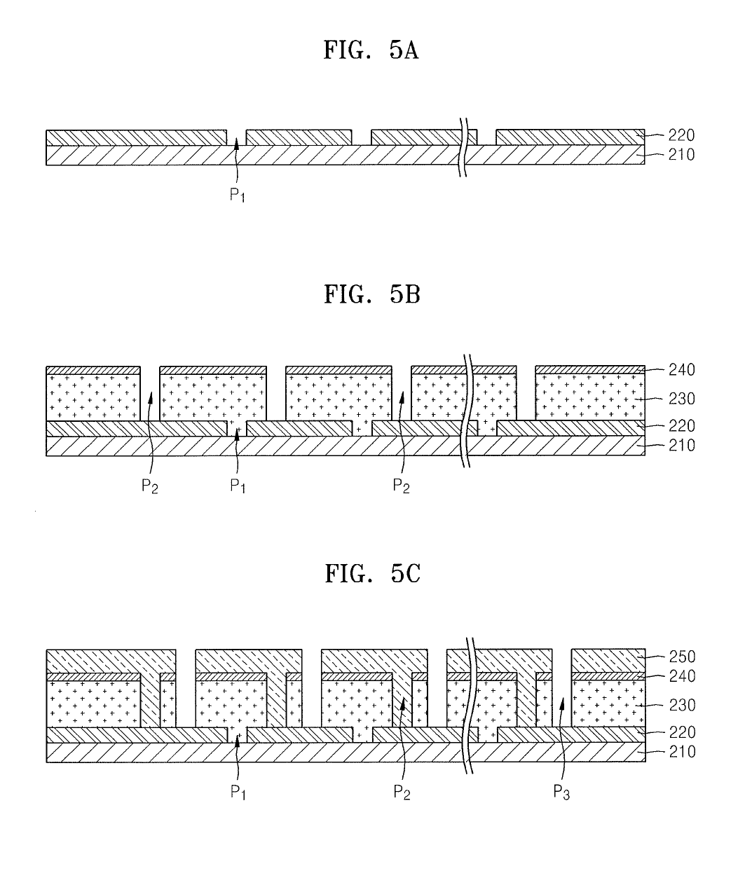

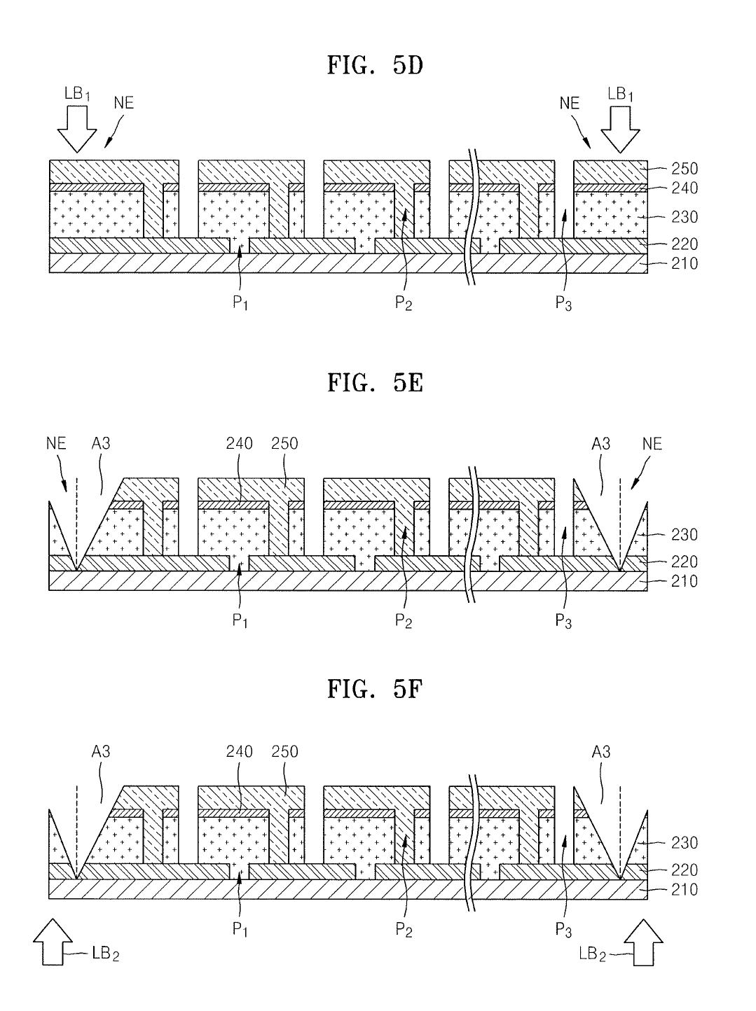

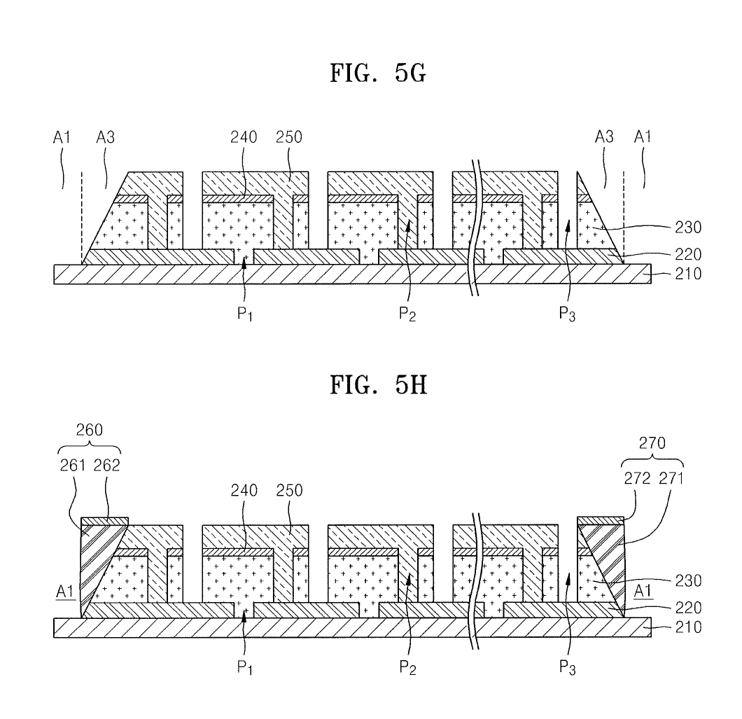

FIGS. 5A to 5H illustrate cross-sectional views depicting stages in an exemplary method of manufacturing the solar cell of FIG. 3.

Referring to FIG. 5A, first, a rear electrode layer 220 may be formed on a substrate 210 and divided into a plurality of portions using a first patterning process. The process of forming the rear electrode layer 220 and the first patterning process may be the same as described above with reference to FIG. 4A.

Referring to FIG. 5B, a light absorption layer 230 and a buffer layer 240 may be formed, and a second separation groove P2 may be formed using a second patterning process. The process of forming the light absorption layer 230 and the buffer layer 240 and the second patterning process using a mechanical scribing process or a laser scribing process may be similar to as described above with reference to FIG. 4B. However, the process described with reference to FIG. 5B may differ from the process described with reference to FIG. 4B in that a second separation groove P2 may be formed in regions of the light absorption layer 230 and the buffer layer 240 corresponding to at least one of the non-generation regions NE.

Referring to FIG. 5C, a transmissive electrode layer 250 may be formed, and a third patterning process may be performed. The process of forming the transmissive electrode layer 250 and the third patterning process may be the same as described above with reference to 4C. Since at least one of the non-generation regions NE includes the second separation groove P2, the transmissive electrode layer 250 may be in contact with the rear electrode layer 220 in the non-generation region NE. The transmissive electrode layer 250 may be formed to have a textured top surface (not shown).

Referring to FIGS. 5D and 5E, portions of the non-generation regions NE may be selectively removed using laser beams LB1 to form electrode regions A3. The removal of the non-generation regions NE may be performed using a laser scribing process as described above with reference to FIGS. 4D and 4E. The laser beams LB1 may be used in both the non-generation regions NE, i.e., including the non-generation region NE having the second separation groove P2, to form V-shaped grooves. For example, each portion of the non-generation region NE may be removed to form inclined surface of the rear electrode layer 220 to increase contact area between the rear electrode layer 220 and at least one of the first and second electrodes 260 and 270 to be formed during a subsequent process.

When a portion of a left non-generation region NE is removed, a region removed due to laser beams LB1 may be disposed on a left side of the second separation groove P2 formed in the left non-generation region NE. For example, the electrode region A3 in the left non-generation region NE may be between the second separation groove P2 and the later formed edge region A1. The second separation groove P2 may serve as a by-pass pathway in the left non-generation region NE.

In the method of manufacturing a solar cell according the exemplary embodiment, lateral surfaces of the rear electrode layer 220 may include inclined surfaces due to the laser scribing process. A slope of the lateral surface of the rear electrode layer 220, e.g., an angle of the lateral surface to a bottom-most surface of the rear electrode layer 220 may range from about 30° to about 75°, e.g., from about 45° to about 60°.

Referring to FIGS. 5F and 5G, an edge isolation process may be performed. For example, the rear electrode layer 220, the light absorption layer 230, the buffer layer 240, and the transmissive electrode layer 250 disposed in a region adjacent to the electrode region A3, e.g., disposed right next to the electrode region A3 may be removed to form the edge region A1. The edge isolation process may be performed using laser beams LB2 as described above with reference to FIGS. 4F and 4G.

The process of forming the electrode regions A3 and the edge isolation process for forming the edge region A1, e.g., described with reference to FIGS. 5D, 5E, 5F, and 5G, may be simultaneously performed in the same equipment by varying an output and direction of laser beams as described above.

Referring to FIG. 5H, first and second electrodes 260 and 270 may be formed. The first and second electrodes 260 and 270 may include first and second conductive layers 261 and 271 and first and second bus bars 262 and 272, respectively. The formation of the first and second electrodes 260 and 270 may be performed in the same manner as described with reference to FIG. 4H.

By way of summation and review, to enable the manufacturing of highly efficient photoelectric devices, e.g., solar cells, a Group I-III-V chalcogenide-based compound semiconductor that has a direct-transition energy band structure and a high light absorption coefficient may be used. The Group I-III-V chalcogenide-based compound semiconductor, which may have excellent electrical/optical stability, may be effectively used as a light absorption layer of solar cells. Solar cells using a chalcogenide-based compound have been highlighted as solar cells capable of improving economical efficiency of solar light generation in substitute for a higher-priced crystalline silicon solar cell.

Exemplary embodiments relate to a solar cell that may use a chalcogenide-based compound. The solar cell may include at least one electrode in a non-generation region in which the electrode includes an inclined side extending at an acute angle from the substrate. Accordingly, a contact area between the electrode and another element, e.g., a rear electrode, may be increased while minimizing a surface area of the non-generation region.

Example embodiments have been disclosed herein, and although specific terms are employed, they are used and are to be interpreted in a generic and descriptive sense only and not for purpose of limitation. Descriptions of features or aspects within each embodiment should typically be considered as available for other similar features or aspects in other embodiments. For example, in some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoelectric device, comprising:
a substrate that includes a generation region and a non-generation region, the non-generation region being adjacent to the generation region;
at least one photoelectric conversion unit in the generation region; and
at least one electrode in the non-generation region, the electrode including an inclined side extending at an acute angle from the substrate.

2. The photoelectric device as claimed in claim 1, wherein the acute angle of the inclined side is about 30° to about 75° with respect to an upper surface of the substrate.

3. The photoelectric device as claimed in claim 2, wherein the acute angle is about 45° to about 60°.

4. The photoelectric device as claimed in claim 2, wherein a lowermost end of the inclined side of the electrode is in contact with the upper surface of the substrate and the inclined side abuts a rear electrode on the upper surface of the substrate.

5. The photoelectric device as claimed in claim 2, wherein another side of the electrode is opposite the inclined side of the electrode and extends from the upper surface of the substrate.

6. The photoelectric device as claimed in claim 1, further comprising a rear electrode layer on the substrate, the rear electrode layer including at least one rear electrode extending from the generation region to the non-generation region, and a lateral end of the one rear electrode in the non-generation region being in contact with the inclined side of the electrode.

7. The photoelectric device as claimed in claim 6, further comprising an isolation region adjacent to the electrode having the inclined side and spaced apart from the at least one rear electrode.

8. The photoelectric device as claimed in claim 6, wherein the lateral end of the one rear electrode is inclined.

9. The photoelectric device as claimed in claim 6, wherein substantially an entirety of the one lateral end of the rear electrode abuts the inclined side of the electrode.

10. The photoelectric device as claimed in claim 6, wherein:
in the generation region, a light absorption layer, a buffer layer, and a transmissive electrode layer are sequentially stacked on the rear electrode layer to form the at least one photoelectric conversion unit, and
in the non-generation region, the light absorption layer, the buffer layer, and the transmissive electrode layer abut the inclined side of the electrode.

11. The photoelectric device as claimed in claim 10, wherein, in the non-generation region, the light absorption layer, the buffer layer, and the transmissive electrode layer abut a conductive layer of the electrode that forms the inclined side.

12. The photoelectric device as claimed in claim 11, wherein a bus bar of the electrode covers the conductive layer and is adjacent to an uppermost surface of the transmissive electrode layer.

13. The photoelectric device as claimed in claim 10, wherein a stacked structure in the non-generation region including the rear electrode, the light absorption layer, the buffer layer, and the transmissive electrode layer has a sloped side extending from the substrate at substantially a same angle as the acute angle of the inclined side of the electrode.

14. The photoelectric device as claimed in claim 10, wherein the transmissive electrode layer is in electrical contact with the inclined side and is electrically connected to the one rear electrode such that the transmissive electrode layer provides a by-pass pathway.

15. A method of manufacturing a photoelectric device, the method comprising:
providing a substrate that includes a generation region and a non-generation region, the non-generation region being adjacent to the generation region;
forming stacked structures in the generation region and the non-generation region, one stacked structure in the generation region corresponding to a photoelectric conversion unit;
patterning one stacked structure in the non-generation region to form a trench that has an inclined sidewall and that exposes the substrate; and
forming an electrode in the non-generation region, the forming of the electrode includes depositing a conductive material in the trench such that the electrode includes an inclined side extending at an acute angle from the substrate.

16. The method as claimed in claim 15, wherein forming the electrode includes performing a first laser scribing process to form the trench and includes performing a second laser scribing process to remove another sidewall of the trench to form an isolation region.

17. The method as claimed in claim 15, wherein:
forming the stacked structures includes sequentially stacking a plurality of layers including a rear electrode layer, a light absorption layer, a buffer layer, and a transmissive electrode layer on the substrate, and
patterning the one stacked structure in the non-generation region includes forming the trench through each of the plurality of layers in the one stacked structure.

18. The method as claimed in claim 17, wherein forming the electrode includes removing portions of the plurality of layers adjacent to another sidewall of the trench, the other sidewall of the trench being opposite the inclined sidewall of the trench.

19. The method as claimed in claim 18, wherein the portions of the plurality of layers are removed by a second laser scribing process such that the electrode includes the inclined side and another side extending from the substrate.

20. The method as claimed in claim 15, wherein forming the trench includes patterning a rear electrode in the non-generation region such that a lateral end of the rear electrode has a slope that corresponds to a slope of the inclined side of the electrode, and the lateral end of the rear electrode abuts the inclined side of the electrode.
